(19) United States
(12) Patent Application Publication
(10) Pub. No.: US 2026/0362806 A1
(43) Pub. Date: Nov. 12, 2026

(54) TFT BACKPLANE FOR ELECTRONIC PAPER

(71) Applicant: JIANGXI XINGTAI TECHNOLOGY INC., Ji'an, Jiangxi (CN)

(72) Inventors: Jun Zhang, Ji'an, Jiangxi (CN); Wei He, Ji'an, Jiangxi (CN); Ziping Hu, Ji'an, Jiangxi (CN); Xuming Xiao, Ji'an, Jiangxi (CN)

(21) Appl. No.: 19/153,616

(22) PCT Filed: Dec. 16, 2024
(86) PCT No.: PCT/CN2024/139471

§ 371 Date: Aug. 5, 2025

(30) Foreign Application Priority Data
Oct. 18, 2023 (CN) 202322794045.8

(51) Int. Cl. H10D 86/40; G02F 1/1685; H10D 86/60

(52) U.S. Cl. CPC H10D 86/441; G02F 1/1685; H10D 86/60

(57) ABSTRACT

The TFT backplane comprises a display area that is provided with a first chamfer portion, and a non-display area that is located on a periphery of the display area and is provided with a second chamfer portion positioned corresponding to and shaped complementary to the first chamfer portion; a silver paste connection area positioned in the second chamfer portion of the non-display area comprises a common electrode layer, a first insulating layer, a metal layer, a second insulating layer, and a pixel electrode layer; the first and second insulating layers are provided with a first or second layer via hole for enabling conductivity, respectively; all data scanning lines and gate scanning lines of the display area are laid out on the non-display area, bypassing the silver paste connection area; and the data scanning lines are arranged in a gap between the silver paste connection area and the display area.

### TECHNICAL FIELD

The disclosure relates to the field of display technology, more particularly to a TFT backplane for electronic paper.

### BACKGROUND

The mass-produced TFT backplane for electronic paper in the prior art comprises a non-display area 1′, a boundary area 4′, and a display area 2′. The display area 2′ has a square shape and is provided, at the tab portions located below, with conductive silver paste holes to form silver paste connection areas 3′. The voltage signals from the TFT backplane can be conducted to the common electrodes on the electronic paper film through the conductive silver paste holes, to enable the driving and display of the electronic paper. However, conventional conductive silver paste holes that extend out would lead to reductions in the cutting and layout efficiency of the electronic paper and space utilization of the TFT backplane, detrimental to reduce production costs. Furthermore, in order to establish electrical connections with the driver IC, the gate scanning lines on the TFT backplane need to pass through both sides of the display area and then bypass the conductive silver paste holes. It results that the backplane routing occupies more space and thus the screen-to-body ratio of the electronic paper is reduced.

### SUMMARY

The disclosure is to provide a TFT backplane for electronic paper. It can provide the first chamfer portion in the display area such that the silver paste connection area can be provided in the non-display area, thereby enhancing the cutting and layout efficiency of the electronic paper, and improving its aesthetic appeal.

In order to achieve the above goal, the disclosure provides a TFT backplane for electronic paper, which comprises an electronic paper film provide with a conductive silver paste dot, wherein the TFT backplane for electronic paper comprises a display area and a non-display area, at least two corners of the display area are each provided with a first chamfer portion, the non-display area is located on a periphery of the display area and is provided with a second chamfer portion positioned corresponding to and shaped complementary to the first chamfer portion of the display area; a silver paste connection area is provided in the non-display area at a position corresponding to the conductive silver paste dot and is positioned in the second chamfer portion of the non-display area; the silver paste connection area comprises a common electrode layer, a first insulating layer, a metal layer, a second insulating layer, and a pixel electrode layer, which are arranged on a substrate from top to bottom; the first insulating layer is provided with a first layer via hole for enabling conductivity between the common electrode layer and the metal layer, the second insulating layer is provided with a second layer via hole for enabling conductivity between the metal layer and the pixel electrode layer; the pixel electrode layer is electrically connected to the conductive silver paste dot; all data scanning lines and all gate scanning lines of the display area are laid out on the non-display area, bypassing the silver paste connection area; the data scanning lines and the gate scanning lines are respectively positioned on opposite sides of the silver paste connection area, and the data scanning lines are arranged in a gap between the silver paste connection area and the display area.

In a preferred solution of the disclosure, a boundary area may be defined between the display area and the non-display area, dummy pixels may be arranged in an array within the boundary area, and normal pixels may be arranged in an array within the display area.

A spacing between an edge of the silver paste connection area and an edge of the boundary area may range from 0.2 mm to 3 mm.

In a preferred solution of the disclosure, the first chamfer portion may be a round chamfer or an oblique chamfer.

In a preferred solution of the disclosure, the round chamfer of the first chamfer portion may have a concave or convex arc.

In a preferred solution of the disclosure, four corners of the display area may be each provided with the first chamfer portion.

In a preferred solution of the disclosure, the conductive silver paste dot may comprise two conductive silver paste dots provided on both left and right sides of a lower portion of the display area, respectively; two sides of a lower portion of the boundary area may have a rounded structure, and two sides of an upper portion of the boundary area may have a right-angle structure.

In a preferred solution of the disclosure, the conductive silver paste dot may comprise two conductive silver paste dots provided on either left side or right side of the display area, respectively; two corners of the boundary area proximal to the two conductive silver paste dots may be rounded, and two corners of the boundary area distal to the two conductive silver paste dots may be right-angled.

In a preferred solution of the disclosure, a number of the conductive silver paste dots may range from 1 to 4.

Compared with the existing technologies, the TFT backplane for electronic paper of the disclosure has advantages as follows.

As the disclosure provides the first chamfer portion in the display area to allow the silver paste connection area to be provided in the non-display area, it can save space, effectively increase the screen-to-body ratio, enhance the cutting and layout efficiency of the electronic paper, and improve its aesthetic appeal. Moreover, as the gate scanning lines and data scanning lines are respectively positioned on two sides of the silver paste connection area, it can facilitate zoned wiring and reduce the complexity of layout design.

### BRIEF DESCRIPTION OF THE DRAWINGS

To make technical solutions of embodiments of the present disclosure clearer, the accompanying drawings of the embodiments will be briefly explained below.

FIG. 1 is a schematic drawing of a TFT backplane for electronic paper in the prior art;

FIG. 2 is a schematic drawing of a TFT backplane for electronic paper of the disclosure;

FIG. 3 is a schematic diagram of wiring that illustrates gate scanning lines and data scanning lines of the disclosure;

FIG. 4 is a cross-sectional view taken along the direction A-A in FIG. 3;

FIG. 5 is a schematic drawing illustrating a boundary area of a TFT backplane for electronic paper in a first embodiment of the disclosure;

FIG. 6 is a schematic drawing illustrating a boundary area of a TFT backplane for electronic paper in a second embodiment of the disclosure.

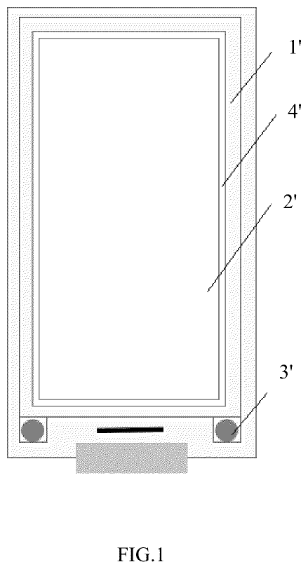

In the drawings, 1. non-display area; 2. display area; 21. the first chamfer portion; 22. gate scanning lines; 23. data scanning lines; 24. the gate layer; 25. the pixel common electrode layer; 26. the source layer; 27. the drain layer; 28. the semiconductor layer; 3. silver paste connection area; 31. the substrate; 32. common electrode layer; 33. first insulating layer; 331. the first layer via hole; 34. the metal layer; 35. second insulating layer; 351. the second layer via hole; 36. the pixel electrode layer; 4. boundary area; 5. electronic paper film; 51. the silver paste dot.

### DETAILED DESCRIPTION OF ILLUSTRATED EMBODIMENTS

The embodiments of the disclosure will be further explained below in detail with reference to drawings and particular examples. The following examples serve to illustrate the disclosure, but are not intended to limit the disclosure.

It should be understood that the terms, such as “upper”, “lower”, “left”, “right”, “top”, “bottom”, and the like as used in the description, refer to position and orientation relationships as shown in the drawings for convenience of description and for the purpose of simplicity. They are not intended to indicate or hint a limitation in terms of specific orientation or configuration and operation with specific orientation to the described device or element, and should not be regarded as a limitation to the present disclosure. It should be understood that the terms “first” and “second”, and the like used in the description to illustrate various information, are merely used to distinguish one information from another and are not intended to limit the scope of the information. For example, “first” information may be referred to as “second” information, and similarly “second” information may be referred to as “first” information, without departing from the scope of the disclosure.

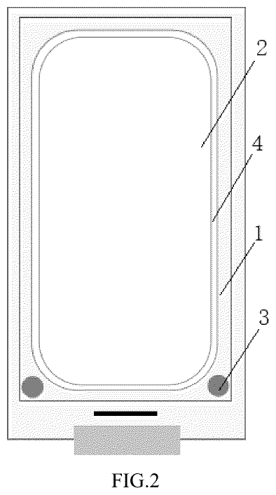

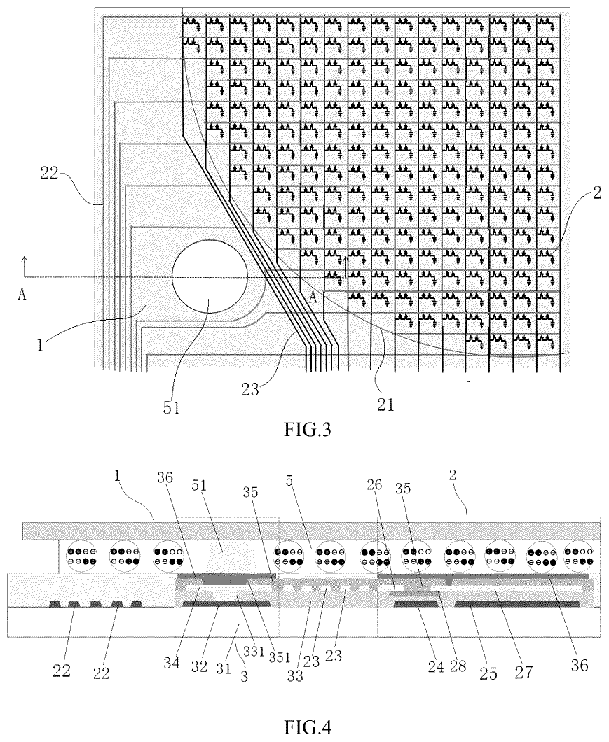

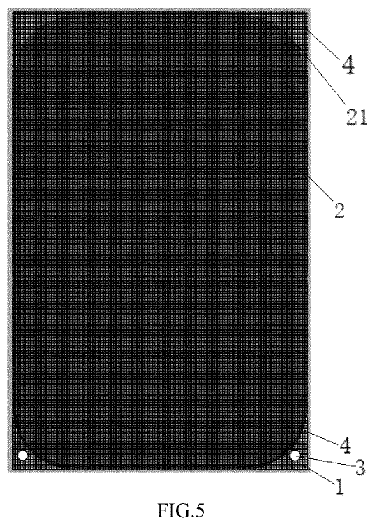

Referring to FIGS. 2-6, a TFT backplane for electronic paper is provided in a preferred embodiment of the disclosure. The TFT backplane for electronic paper comprises an electronic paper film 5 which is provide with a conductive silver paste dot 51. The TFT backplane for electronic paper comprises a display area 2 and a non-display area 1. At least two corners of the display area 2 are each provided with a first chamfer portion 21. The non-display area 1 is located on the periphery of the display area 2 and is provided with a second chamfer portion positioned corresponding to and shaped complementary to the first chamfer portion 21. A silver paste connection area 3 is arranged in the non-display area 1, at a position corresponding to the conductive silver paste dot 51. The silver paste connection area 3 is positioned within the second chamfer portion of the non-display area 1. The silver paste connection area 3 comprises a common electrode layer 32, a first insulating layer 33, a metal layer 34, a second insulating layer 35, and a pixel electrode layer 36, which are arranged on the substrate 31 from top to bottom. The first insulating layer 33 is provided with a first layer via hole 331 for enabling conductivity between the common electrode layer 32 and the metal layer 34. The second insulating layer 35 is provided with a second layer via hole 351 for enabling conductivity between the metal layer 34 and the pixel electrode layer 36. The pixel electrode layer 36 is electrically connected to the conductive silver paste dot 51. All data scanning lines 23 and all gate scanning lines 22 of the display area 2 are laid out on the non-display area 1, bypassing the silver paste connection area 3. The data scanning lines 23 and the gate scanning lines 22 are respectively positioned on two opposite sides of the silver paste connection area 3, with the data scanning lines 23 being arranged in the gap between the silver paste connection area 3 and the display area 2. The metal layer 34 may be either the source layer or the drain layer.

By providing the first chamfer portion 21 in the display area 2, the disclosure can provide an area for defining the silver paste connection area 3 in the non-display area 1. In this way, it can save space, effectively increase the screen-to-body ratio, enhance the cutting and layout efficiency of the electronic paper, and improve its aesthetic appeal. Moreover, as the gate scanning lines 22 and data scanning lines 23 are respectively positioned on two sides of the silver paste connection area 3, it can facilitate zoned wiring and reduce the complexity of layout design.

Exemplarily, a boundary area 4 may be provided between the display area 2 and the non-display area 1, with dummy pixels being arranged in an array within the boundary area 4 and normal pixels being arranged in an array within the display area 2. By additionally providing the boundary area 4, the display performance of the display area 2 can be enhanced. In particular, in such a case that the silver paste connection area 3 is located within the non-display area 1, the spacing between the edge of the silver paste connection area 3 and the edge of the boundary area 4 ranges from 0.2 mm to 3 mm. The data scanning lines 23 and gate scanning lines 22 are closely arranged to minimize space occupation. in such a case that no boundary area 4 is provided on the periphery of the display area 2, the spacing between the edge of the silver paste connection area 3 and the edge of the display area 2 ranges from 0.2 mm to 3 mm.

Exemplarily, the first chamfer portion 21 may be a round chamfer that makes the edge of the display area 2 smoother and more fluent, with the arc eliminating edge sharpness. Apparently, in a further embodiment, the first chamfer portion 21 may be an oblique chamfer. Exemplarily, the first chamfer portion may be an outer chamfer, and the second chamfer portion may be an inner chamfer. Alternatively, the round chamfer of the first chamfer portion may have a concave or convex arc.

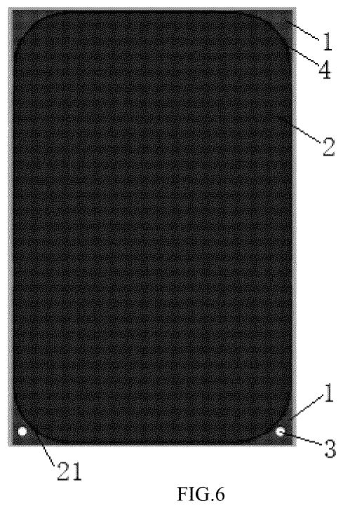

In particular, four corners of the display area 2 are each provided with the first chamfer portion 21, with the symmetrical overall look improving its aesthetic appeal. As shown in FIG. 5, in the first embodiment, two conductive silver paste dots 51 are provided on both left and right sides of the lower portion of the display area 2, respectively. Two sides of the lower portion of the boundary area 4 have a rounded structure, and two sides of the upper portion of the boundary area 4 have a right-angle structure. Furthermore, the boundary area 4 is located in the space outer than the two first chamfer portions 21 at the upper portion of the display area 2, and the gap formed by the first chamfer portion 21 is filled with dummy pixels, to improve the display quality of the display area 2. As shown in FIG. 6, in the second embodiment, all four corners of the boundary area 4 have a rounded structure.

Exemplarily, the number of the conductive silver paste dots 51 may range from 1 to 4, with a maximum of one conductive silver paste dot 51 being placed in each of the second chamfer portions of the non-display area 1. The number of the conductive silver paste dots 51 can be selected based on actual circumstances. In the implementation, the number of the conductive silver paste dots 51 is preferably 2.

Exemplarily, both corners of the lower portion of the display area 2 are provided with the first chamfer portions 21, and both corners of the upper portion of the display area 2 are right-angled, thereby increasing the screen-to-body ratio. In a further embodiment, all four corners of the display area 2 are provided with the first chamfer portions 21, with the symmetrical overall look improving its aesthetic appeal. Besides, in a further embodiment, two conductive silver paste dots 51 may be provided, on either left side or right side of the display area 2, respectively. The two corners of the boundary area 4 proximal to the two conductive silver paste dots 51 are rounded, and the two corners of the boundary area 4 distal to the two conductive silver paste dots 51 are right-angled.

All the above are merely some preferred embodiments of the disclosure. It should be noted that those skilled in the art may obtain modifications and equivalents without departing from the technical principle of the disclosure. The disclosure is intended to cover such modifications and equivalents.

1. A TFT backplane for electronic paper, comprising an electronic paper film provide with a conductive silver paste dot,
wherein the TFT backplane for electronic paper comprises a display area and a non-display area, at least two corners of the display area are each provided with a first chamfer portion, the non-display area is located on a periphery of the display area and is provided with a second chamfer portion positioned corresponding to and shaped complementary to the first chamfer portion of the display area; a silver paste connection area is provided in the non-display area at a position corresponding to the conductive silver paste dot and is positioned in the second chamfer portion of the non-display area; the silver paste connection area comprises a common electrode layer, a first insulating layer, a metal layer, a second insulating layer, and a pixel electrode layer, which are arranged on a substrate from top to bottom; the first insulating layer is provided with a first layer via hole for enabling conductivity between the common electrode layer and the metal layer, the second insulating layer is provided with a second layer via hole for enabling conductivity between the metal layer and the pixel electrode layer; the pixel electrode layer is electrically connected to the conductive silver paste dot; all data scanning lines and all gate scanning lines of the display area are laid out on the non-display area, bypassing the silver paste connection area; the data scanning lines and the gate scanning lines are respectively positioned on opposite sides of the silver paste connection area, and the data scanning lines are arranged in a gap between the silver paste connection area and the display area.

2. The TFT backplane for electronic paper according to claim 1, wherein a boundary area is defined between the display area and the non-display area, wherein dummy pixels are arranged in an array within the boundary area and normal pixels are arranged in an array within the display area.

3. The TFT backplane for electronic paper according to claim 2, wherein a spacing between an edge of the silver paste connection area and an edge of the boundary area ranges from 0.2 mm to 3 mm.

4. The TFT backplane for electronic paper according to claim 2, wherein the first chamfer portion is a round chamfer or an oblique chamfer.

5. The TFT backplane for electronic paper according to claim 4, wherein the round chamfer of the first chamfer portion has a concave or convex arc.

6. The TFT backplane for electronic paper according to claim 4, wherein four corners of the display area are each provided with the first chamfer portion.

7. The TFT backplane for electronic paper according to claim 6, wherein the conductive silver paste dot comprises two conductive silver paste dots provided on both left and right sides of a lower portion of the display area, respectively; two sides of a lower portion of the boundary area have a rounded structure, and two sides of an upper portion of the boundary area have a right-angle structure.

8. The TFT backplane for electronic paper according to claim 6, wherein the conductive silver paste dot comprises two conductive silver paste dots provided on either left side or right side of the display area, respectively; two corners of the boundary area proximal to the two conductive silver paste dots are rounded, and two corners of the boundary area distal to the two conductive silver paste dots are right-angled.

9. The TFT backplane for electronic paper according to claim 1, wherein a number of the conductive silver paste dots ranges from 1 to 4.
